(19) United States
(12) Patent Application Publication
(10) Pub. No.: US 2020/0035725 A1
(43) Pub. Date: Jan. 30, 2020

(54) PHOTODETECTOR, IMAGING ELEMENT, AND OPTICAL SEMICONDUCTOR DEVICE

(71) Applicant: FUJITSU LIMITED, Kawasaki-shi (JP)

(72) Inventors: Ryo Suzuki, Fujisawa (JP); Shigekazu Okumura, Setagaya (JP); Koji Tsunoda, Atsugi (JP)

(73) Assignee: FUJITSU LIMITED, Kawasaki-shi (JP)

(21) Appl. No.: 16/458,533

(22) Filed: Jul. 1, 2019

(30) Foreign Application Priority Data
Jul. 26, 2018 (JP) 2018-140281

(51) Int. Cl. H01L 27/146

(52) U.S. Cl. CPC H01L 27/14607; H01L 27/14669; H01L 27/14694

(57) ABSTRACT

An apparatus includes a substrate that has a plane orientation inclined from a (100) plane such that an inclination angle to a [0-11] direction or a [01-1] direction is larger than an inclination angle to a [011] direction and a [0-1-1] direction, or inclined from a (010) plane such that an inclination angle to a [10-1] direction or a [−101] direction is larger than an inclination angle to a [101] direction and a [−10-1] direction, or inclined from a (001) plane such that an inclination angle to a [−110] direction or a [1-10] direction is larger than an inclination angle to a [110] direction and the [−1-10] direction; and a light-receiving layer disposed above the substrate and having a structure in which a plurality of semiconductor layers are stacked.

### CROSS-REFERENCE TO RELATED APPLICATION

This application is based upon and claims the benefit of priority of the prior Japanese Patent Application No. 2018-140281, filed on Jul. 26, 2018, the entire contents of which are incorporated herein by reference.

### FIELD

The embodiments discussed herein are related to a photodetector, an imaging element, and an optical semiconductor device.

### BACKGROUND

There have been optical semiconductor devices (such as light-receiving devices, such as infrared detectors, and light-emitting devices, for example) that include light-receiving layers or light-emitting layers each having a structure in which a plurality of semiconductor layers are stacked above a substrate.

Related techniques are disclosed in, for example, Japanese Laid-open Patent Publication Nos. 7-221389 and 10-154643.

### SUMMARY

According to an aspect of the embodiments, an apparatus includes a substrate that has a plane orientation inclined from a (100) plane such that an inclination angle to a [0-11] direction or a [01-1] direction is larger than an inclination angle to a [011] direction and a [0-1-1] direction, or inclined from a (010) plane such that an inclination angle to a [10-1] direction or a [−101] direction is larger than an inclination angle to a [101] direction and a [−10-1] direction, or inclined from a (001) plane such that an inclination angle to a [−110] direction or a [1-10] direction is larger than an inclination angle to a [110] direction and the [−1-10] direction; and a light-receiving layer disposed above the substrate and having a structure in which a plurality of semiconductor layers are stacked.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF DRAWINGS

FIG. 1 is a diagram for explaining a configuration of an infrared detector (an optical semiconductor device) according to an embodiment;

FIG. 2 is a diagram for explaining the configuration of the infrared detector (the optical semiconductor device) according to the embodiment;

FIGS. 3A and 3B are diagrams for explaining a plane index and an orientation in the Specification;

FIGS. 4A and 4B are diagrams for explaining inclinations of substrates;

FIGS. 5A and 5B are diagrams for explaining operations and effects of the infrared detector (the optical semiconductor device) according to the embodiment;

FIG. 6 is a graph for explaining operations and effects of the infrared detector (the optical semiconductor device) according to the embodiment;

FIG. 7 is a graph for explaining the problem to be solved by the embodiment;

FIG. 8 is a diagram for explaining the problem to be solved by the embodiment;

FIG. 9 is a diagram for explaining the configuration of the infrared detector (the optical semiconductor device) according to the embodiment;

FIG. 10 is a cross-sectional view for explaining the configuration of a specific configuration example of the infrared detector (the optical semiconductor device) according to the embodiment and a method of manufacturing the same;

FIG. 11 is a cross-sectional view for explaining the method of manufacturing the specific configuration example of the infrared detector (the optical semiconductor device) according to the embodiment;

FIG. 12 is a cross-sectional view for explaining the method of manufacturing the specific configuration example of the infrared detector (the optical semiconductor device) according to the embodiment;

FIG. 13 is a cross-sectional view for explaining the method of manufacturing the specific configuration example of the infrared detector (the optical semiconductor device) according to the embodiment;

FIG. 14 is a cross-sectional view for explaining the method of manufacturing the specific configuration example of the infrared detector (the optical semiconductor device) according to the embodiment;

FIG. 15 is a cross-sectional view for explaining the configuration of the specific configuration example of the infrared detector (the optical semiconductor device) according to the embodiment and a method of manufacturing the same;

FIG. 16 is a schematic diagram illustrating a configuration example of an imaging element according to an embodiment;

FIG. 17 is a schematic cross-sectional view illustrating the configuration example of the imaging element according to the embodiment; and

FIG. 18 is a schematic diagram illustrating a configuration example of an imaging system according to an embodiment.

### DESCRIPTION OF EMBODIMENTS

For example, in an infrared detector including a light-receiving layer having a structure in which a plurality of semiconductor layers are stacked above a substrate, the cutoff wavelength, which is the wavelength of an infrared ray that triggers absorption, varies very sensitively depending on the film thicknesses of the semiconductor layers stacked. For this reason, it is desirable that the film thickness of each semiconductor layer be precisely controlled. However, due to segregation of a constituent material during the growth of the semiconductor layer, the film thickness of each semiconductor layer is not obtained as desired, making it difficult to stably obtain a desired cutoff wavelength, which leads to a low yield.

Although an infrared detector is given as an example for explanation, the same problem occurs in, for example, a different light-receiving device including a light-receiving layer having a structure in which a plurality of semiconductor layers are stacked above a substrate. The same problem occurs also in, for example, a light-emitting device including a light-emitting layer having a structure in which a plurality of semiconductor layers are stacked above a substrate. In this case, it is difficult to stably obtain a desired light emission wavelength, which leads to a low yield. As described above, an optical semiconductor device including a light-receiving layer or a light-emitting layer having a structure in which a plurality of semiconductor layers are stacked above a substrate has the above-described problem.

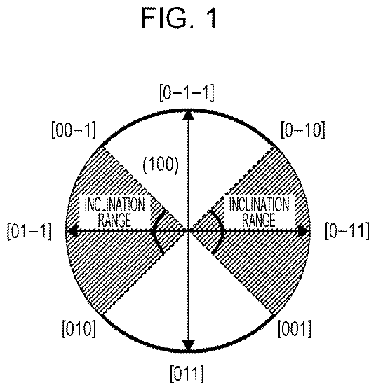

Hereinafter, with the drawings, an optical detector, an imaging element including an image sensor, and an optical semiconductor device according to embodiments are described with reference to FIGS. 1 to 18. The optical semiconductor device according to the embodiment is an optical semiconductor device (a light-receiving device) that operates by absorbing light, and is, for example, an infrared detector that generates carriers by absorbing an infrared ray.

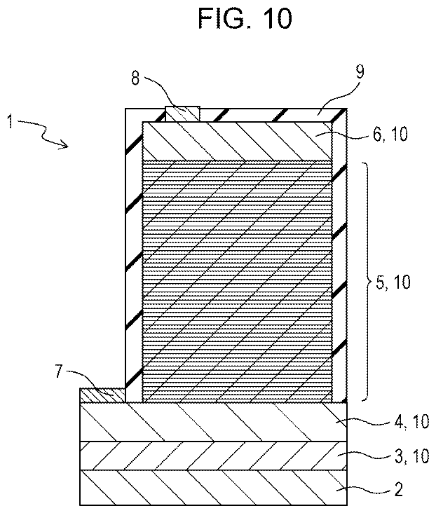

In the embodiment, the infrared detector 1 includes: a substrate 2; and a light-receiving layer 5 disposed above the substrate 2 and having a structure in which a plurality of semiconductor layers are stacked (see for example FIG. 10). The light-receiving layer 5 is also referred to as an absorbing layer. The infrared detector 1 may be, for example, one including: a first electrode layer 4 and a second electrode layer 6 which sandwich a light-receiving layer 5; and a pair of electrodes 7, 8 formed respectively on the first electrode layer 4 and the second electrode layer 6, as in a specific configuration example to be described later (see for example FIG. 10).

The substrate 2 is a compound semiconductor substrate. The substrate 2 is, for example, a GaSb substrate, an InAs substrate, a GaAs substrate, a GaP substrate, an InP substrate, or the like. The plurality of semiconductor layers included in the light-receiving layer 5 are each a compound semiconductor layer. The light-receiving layer 5 has a superlattice structure in which a plurality of III-V-group compound semiconductor layers are stacked as the structure in which the plurality of semiconductor layers are stacked. In this case, the plurality of semiconductor layers are each a III-V-group compound semiconductor layer.

Specifically, the light-receiving layer 5 may have at least a superlattice structure containing two or more of InAs, GaSb, AlSb, and InSb, for example. In other words, the light-receiving layer 5 may include two or more of an InAs layer, a GaSb layer, an AlSb layer, and an InSb layer in the plurality of III-V-group compound semiconductor layers included in the light-receiving layer 5. In addition, the light-receiving layer 5 may contain a mixed crystal of any of InAs, GaSb, AlSb, and InSb.

That is, the light-receiving layer 5 may include any of a mixed crystal layer containing InAs, a mixed crystal layer containing GaSb, a mixed crystal layer containing AlSb, and a mixed crystal layer containing InSb in the plurality of III-V-group compound semiconductor layers included in the light-receiving layer 5. As described above, the light-receiving layer 5 may include two or more of a layer containing InAs (an InAs layer or a mixed crystal layer containing InAs), a layer containing GaSb (an GaSb layer or a mixed crystal layer containing GaSb), a layer containing AlSb (an AlSb layer or a mixed crystal layer containing AlSb), and a layer containing InSb (an InSb layer or a mixed crystal layer containing InSb) in the plurality of II-V-group compound semiconductor layers included in the light-receiving layer 5.

The light-receiving layer 5 may include at least a III-V-group compound semiconductor layer containing In in the plurality of III-V-group compound semiconductor layers included in the light-receiving layer 5. In this case, it is possible to effectively solve the problem caused by the In segregation as described later. When formed as described above, the light-receiving layer 5 has a superlattice structure formed of so-called narrow-gap semiconductors such as InAs and GaSb and mixed crystals thereof, for example.

When the light-receiving layer 5 is formed using the above-described materials, the substrate 2 is preferably a GaSb substrate or an InAs substrate. In particular, in the embodiment, as illustrated in FIG. 1, the substrate 2 has a plane orientation inclined from the (100) plane such that the inclination angle to the [0-11] direction or the [01-1] direction is larger than the inclination angles to the [011] direction and the [0-1-1] direction. For this reason, the substrate 2 is referred to also as an inclined substrate.

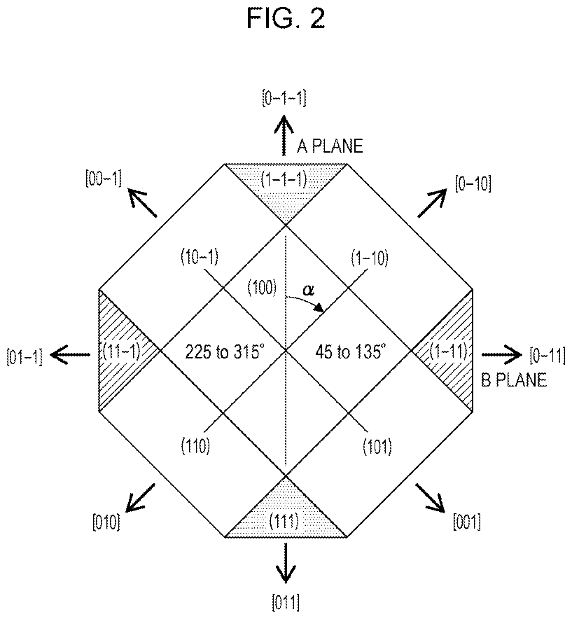

Here, the substrate 2 is inclined in the range of angle including the [0-11] direction out of the ranges of angle from the [0-10] direction to the [001] direction or is inclined in the range of angle including the [01-1] direction out of the ranges of angle from the [010] direction to the [00-1] direction. The range of angle in which the substrate 2 is inclined is referred to also as a range of inclination. In addition, the substrate 2 is inclined to such a direction that based on the [0-1-1] direction, the angle α made by the inclination direction and the [0-1-1] direction is included in the range of angle of 450 to 135° or 225° to 315°, as illustrated in FIG. 2.

The above-described configuration makes it possible to suppress the segregation and improve the yield owing to the stabilization of the cutoff wavelength, in accordance with the operations and effects described below. First, the notations of signs representing a plane index and an orientation in the Specification are defined. To indicate the plane orientation or the direction, the normal practice is to add a bar above a number in parentheses. In the specification, the plane orientation and the direction are expressed by adding a minus sign before a number in parentheses.

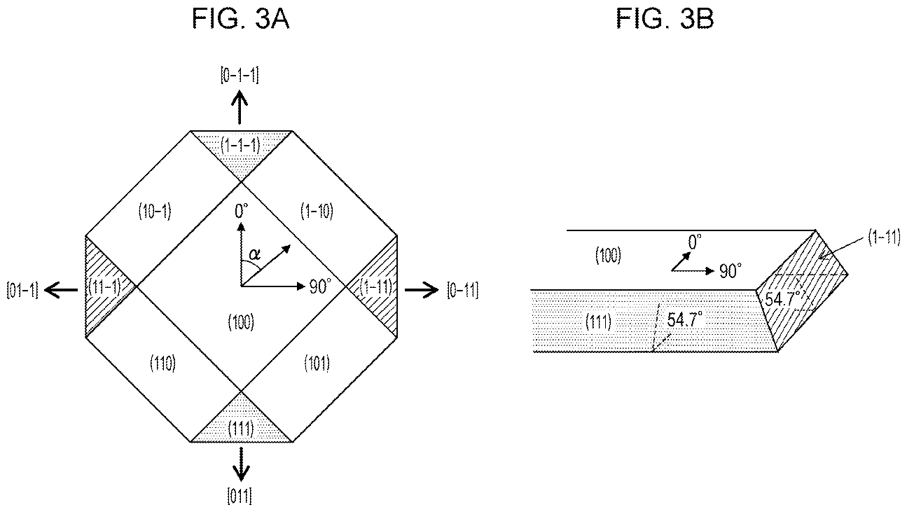

Next, the relation between a plane index and an orientation is described using FIGS. 3A and 3B. As illustrated in FIGS. 3A and 3B, the reference plane is denoted by (100). On the (100) plane, when the [0-1-1] direction is set at 0 degree, the [0-11] direction is a direction rotated clockwise by 90 degrees. Likewise, the [011] direction and the [01-1] direction are directions rotated by 180 degrees and 270 degrees, respectively.

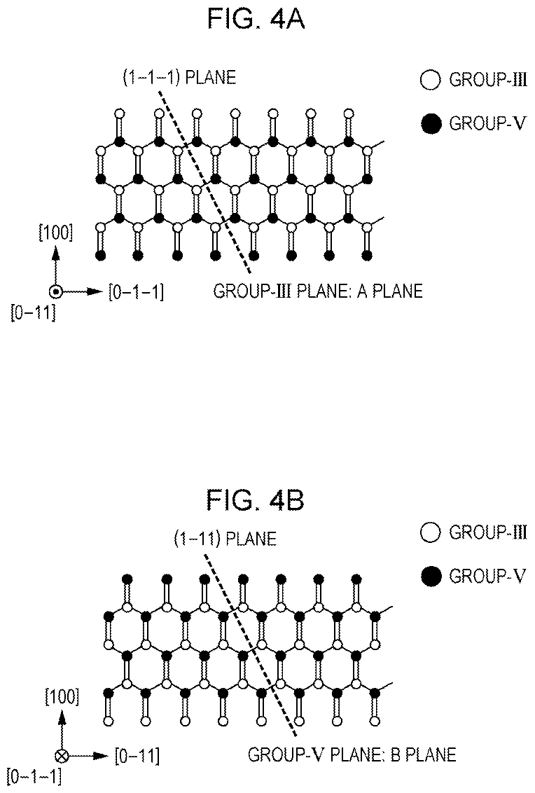

Planes inclined by 54.7 degrees to the [0-1-1] direction or the [011] direction are the (1-1-1) plane and the (111) plane, respectively. For example, in the case of III-V-group compound semiconductors, that is, III-V-group compound semiconductors having a zinc blende structure, the (1-1-1) plane or the (111) plane of these are called the III-group plane or the A plane, as illustrated in FIG. 4A.

On the other hand, as illustrated in FIGS. 3A and 3B, planes inclined by 54.7 degrees to the [0-11] direction or the [01-1] direction are the (1-11) plane and the (11-1) plane, respectively. For example, in the case of III-V-group compound semiconductors, that is, III-V-group compound semiconductors having a zinc blende structure, the (1-11) plane or the (11-1) plane of these are called the V-group plane or the B plane, as illustrated in FIG. 4B.

In the above-described case, the (1-1-1) plane and the (111) plane are crystallographically equivalent to each other. Likewise, the (1-11) plane and the (11-1) plane are crystallographically equivalent to each other. On the other hand, the (1-11) plane and the (11-1) plane are not equivalent to the (1-1-1) plane and the (111) plane. In the specification, the direction in which the substrate 2 is inclined is sometimes described using the angle c by which the direction is rotated clockwise from the [0-1-1] direction supplementarily.

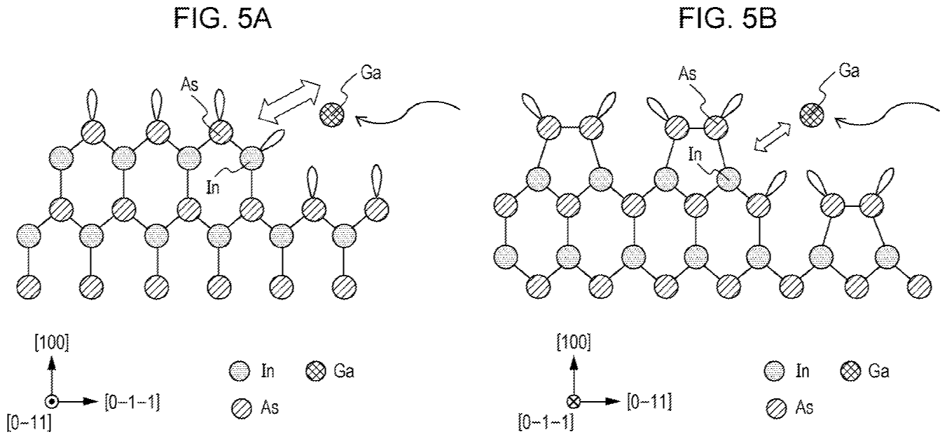

The inclination angle of the substrate 2 indicates the smaller of the angles made by the (100) plane and the inclined plane. FIGS. 5A and 5B schematically illustrate the bonding of atoms near the step edge immediately before GaSb (the GaSb layer) is formed on InAs (the InAs layer), which has been formed on the inclined substrate 2.

FIG. 5A illustrates as an example a case where the plane orientation is inclined from the (100) plane to the [0-1-1] direction, that is, a case where the plane orientation is inclined from the (100) plane toward the (1-1-1) plane (A plane; III-group plane). FIG. 5B illustrates a case where the plane orientation is inclined from the (100) plane to the [0-11] direction, that is, a case where the plane orientation is inclined from the (100) plane toward the (1-11) plane (B plane; V-group plane).

The plane orientation of the substrate 2 is the plane orientation of the surface of the substrate 2. Each of the semiconductor layers formed on the substrate 2 also has the same plane orientation as that of the substrate 2. In the case where the plane orientation is inclined from the (100) plane to the [0-1-1] direction, In atoms near the step edge are bound to adjacent As atoms through two bonds, as illustrated in FIG. 5A.

On the other hand, in the case where the plane orientation is inclined from the (100) plane to the [0-11] direction, In atoms near the step edge are bound to adjacent As atoms through three bonds, as illustrated in FIG. 5B. For this reason, the bonding of In atoms at the step edge is stronger than a case where the plane orientation is inclined from the (100) plane to the [0-1-1] direction. As a result, when Ga atoms are taken in at the step edge, the replacement with In atoms is unlikely to occur, so that segregation of In atoms is unlikely to occur.

Hence, segregation of In is unlikely to occur, so that thinning of the film thickness of the InAs layer is suppressed. As described above, the disclosure utilizes the fact that the film formation is likely to progress at the step edge of the substrate 2, the fact that the bonding state at the step edge largely affects the segregation, and the fact that the bonding state of atoms in the semiconductor layers formed on the substrate 2, particularly the bonding state at the step edge is different depending on the inclination direction of the substrate.

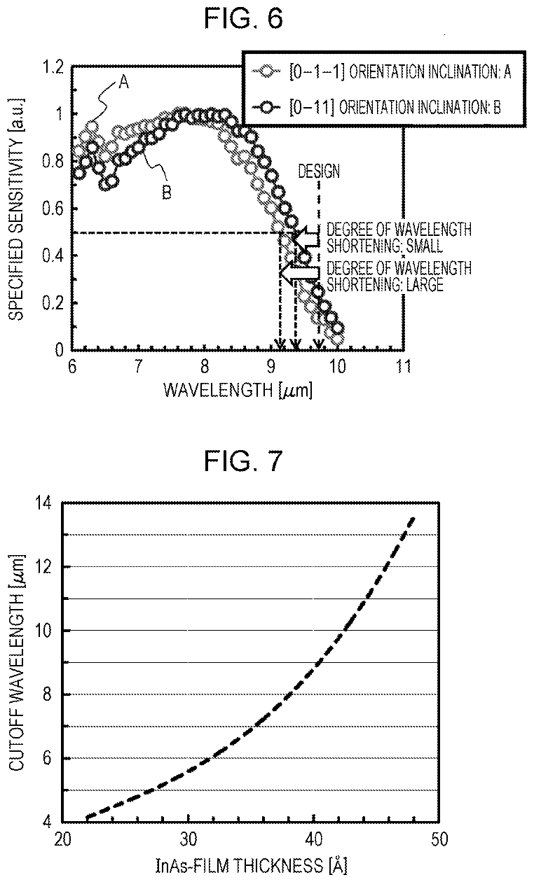

FIG. 6 illustrates comparison of cutoff wavelength between a case where a light-receiving layer 5 having a superlattice structure is formed on a substrate having a plane orientation inclined from the (100) plane to the [0-1-1] direction and a case where a light-receiving layer 5 having the same superlattice structure is formed on a substrate having a plane orientation inclined from the (100) plane to the [0-11] direction. As in the embodiment, forming the light-receiving layer 5 on the substrate 2 inclined from the (100) plane to the [0-11] direction strengthens the bonding of In at the step edge and makes the segregation (surface segregation) of In unlikely to occur. For this reason, as illustrated in FIG. 6, it is possible to suppress the shortening of the cutoff wavelength (absorption wavelength).

This makes it possible to reduce the instability of the cutoff wavelength occurring due to the segregation and to improve the yield. Note that the inclination direction may be the [01-1] direction, and in this case as well, the same effects are obtained. The substrate 2 suffices as long as the inclination angle to the [0-11] direction or the [01-1] direction is larger than the inclination angle to the [011] direction and the [0-1-1] direction, and in this case as well, the same effects are obtained.

Here, although the problem which occurs due to the segregation of In in the case where a GaSb layer is formed on an InAs layer as well as the configuration for solving the problem and its effects are described as an example; in the cases of combinations of other elements, the same problem occurs due to the segregation of another element. For example, in the case of a combination of InAs and InAsSb, the same problem occurs due to the segregation of Sb. In this case as well, employing the same configuration as described above allows the same effects to be obtained.

The configuration as described above is because of the following reasons. The type II superlattice (T2SL) has been expected as an alternative next-generation infrared detector material to mercury cadmium telluride (MCT), and widely studied. In many cases, a superlattice structure is formed on a GaSb substrate, using a material such as GaSb, InAs, or AlSb that has a relatively small difference in lattice constant from GaSb.

In a case where a superlattice structure in which InAs and GaSb are alternately stacked is used as a light-receiving layer for infrared rays, the wavelength of the infrared ray to be detected is determined based on the energy difference between the level of bound electrons in the InAs layer and the level of bound holes in the GaSb layer. This energy difference may be controlled by controlling the film thickness of the InAs layer or the GaSb layer. The cutoff wavelength (response wavelength), which is a wavelength of an infrared ray at which absorption starts to occur, changes very sensitively to the film thickness of the InAs layer (see for example FIG. 7).

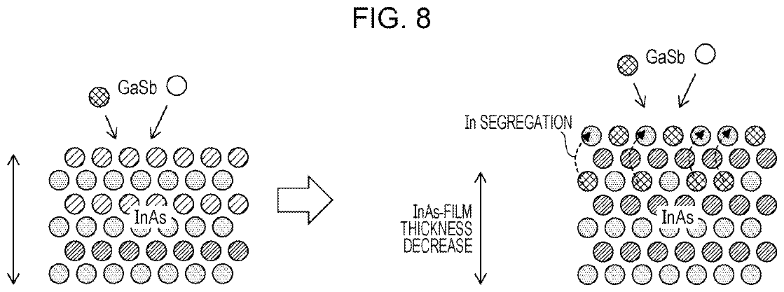

For this reason, it is desirable that the film thickness of the InAs layer be precisely controlled. However, in forming the film of a superlattice for a light-receiving layer, segregation of a constituent material often becomes problematic. For example, when a GaSb layer is stacked on an InAs layer, In is replaced by Ga to cause segregation in the growth surface. The film thickness of the InAs layer thus becomes thinner than the design film thickness (see for example FIG. 8), leading to the shortening of the cutoff wavelength.

The segregation is affected by film growth conditions such as film growth temperature and flux ratio of materials to be supplied. It is thus desirable that the film growth conditions be stabilized. On the other hand, to enhance the absorption efficiency, a light-receiving layer having a large total film thickness of several micrometers is to be formed. During the formation, however, it is difficult to obtain stable film growth conditions. For this reason, there is a problem that it is difficult to obtain a stable cutoff wavelength and the yield becomes low.

In view of this, the above-described configuration is adopted in order to reduce the instability of the cutoff wavelength, which is caused by the segregation, and improve the yield. Here, the description is given of the problem caused by the segregation of In in the infrared detector 1 including a light-receiving layer 5 having a superlattice structure in which InAs and GaSb are alternately stacked, of the configuration to solve the problem and the effects as examples. The same problem however occurs also in a light-receiving device including a light-receiving layer having a structure in which semiconductor layers containing In are stacked, for example. For example, in a light-receiving device including a light-receiving layer having a structure in which a plurality of semiconductor layers made of another material are stacked, the same problem sometimes occurs due to segregation of other elements. For example, in a light-receiving device including a light-receiving layer having a structure in which InAs and InAsSb are stacked, the same problem occurs due to the segregation of Sb. In this case as well, employing the same configuration as described above allows the same effects to be obtained.

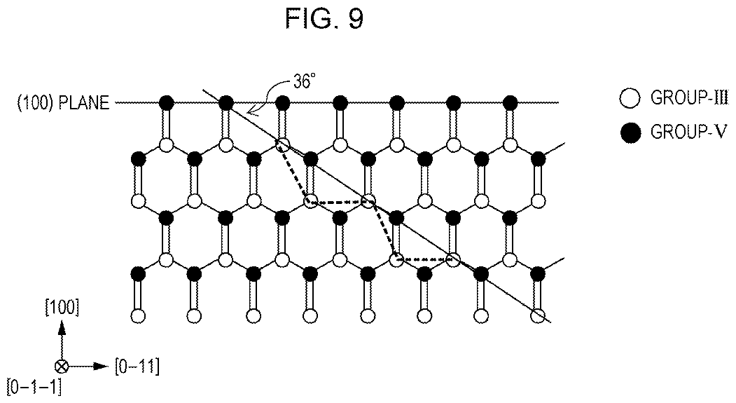

When the above-described configuration is employed, it is preferable that the plane orientation of the substrate 2 be inclined within the range of 360°±1° from the (100) plane to the [0-11] direction or the [01-1] direction as illustrated in FIG. 9, for example. It is also preferable that the substrate 2 be inclined within the range of ±10 about the (2-11) plane or the (21-1) plane.

When the inclination angle from the (100) plane, that is, the inclination angle with the (100) plane being at 0° is set at 36° 01°, the number of the step edges where the segregation is unlikely to occur becomes largest. Accordingly, it is possible to suppress segregation most, to reduce the instability of the cutoff wavelength, which is caused by the segregation, most and to improve the yield most. Hereinafter, specific configuration examples are described with reference to FIGS. 10 to 15.

FIG. 10 is a cross-sectional view illustrating a specific configuration example of an infrared detector 1 according to the embodiment. As illustrated in FIG. 10, a semiconductor stacked structure (stack) 10 included in the infrared detector 1 is epitaxially grown on an n-type GaSb substrate 2. Here, the substrate 2 has a plane orientation inclined from the (100) plane by 0.3° to the [0-11] direction (α=90°), for example.

The epitaxially-grown layer 10 includes a buffer layer 3, a first electrode layer 4, a light-receiving layer 5, and a second electrode layer 6. The buffer layer 3 is a GaSb layer. The first electrode layer 4 is a p-type GaSb layer. The light-receiving layer 5 has a superlattice structure in which InAs and GaSb are alternately stacked. The second electrode layer 6 is an n-type InAs layer.

On the first electrode layer 4 and the second electrode layer 6, electrodes 7, 8, each made of for example Ti/Pt/Au, are formed in contact with the surfaces of these electrodes. On the other surfaces, formed is an insulating film 9 made of for example SiO₂. The infrared detector 1 having the above-described structure may be manufactured as described below. Each of the layers of the semiconductor stacked structure (stack) 10 included in the infrared detector 1 is formed by for example molecular beam epitaxy (MBE).

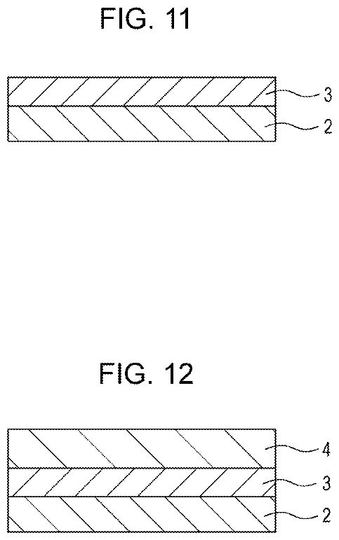

First, for example, the n-type GaSb substrate 2 is introduced into the substrate introduction chamber of the MBE system as illustrated in FIG. 11. Note that the n-type GaSb substrate 2 is subjected to a degassing treatment in the preparation chamber. Next, the n-type GaSb substrate 2 is transported into the growth chamber maintained in ultrahigh vacuum. The n-type GaSb substrate 2 transferred into the growth chamber is heated under a Sb atmosphere in order to remove oxide films on the surface.

After the oxide films are removed as described above, to improve the flatness of the surface of the substrate, as illustrated in FIG. 11, a GaSb buffer layer 3 for example is grown into about 100 nm on the n-type GaSb substrate 2 at a substrate temperature of about 500° C. Next, as illustrated in FIG. 12, the first electrode layer 4 made of p-type GaSb doped with Be and having a hole concentration of about 1×10¹⁸ cm⁻³, for example, is grown on the GaSb buffer layer 3.

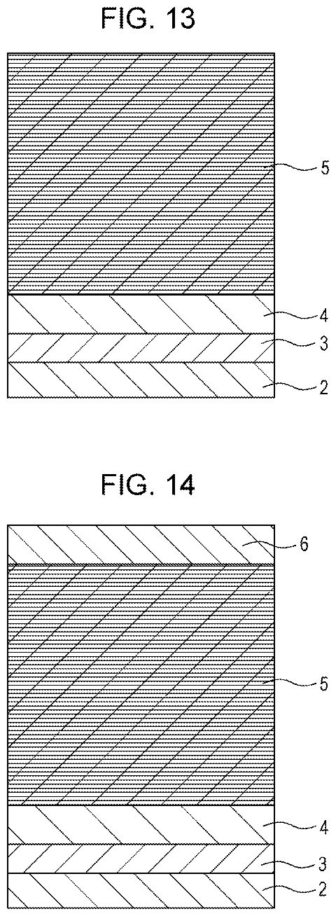

Next, as illustrated in FIG. 13, the light-receiving layer 5 is formed. For example, first, a p-type superlattice is formed. Specifically, undoped InAs is formed into about 4.2 nm, and p-type GaSb doped with Be and having a hole concentration of about 5×10¹⁷ cm⁻³ is formed into about 2.1 nm. This formation of InAs and GaSb is counted as one cycle, and is repeated for example 50 cycles.

Next, an i-type superlattice is formed. Specifically, undoped InAs is formed into about 4.2 nm, and undoped GaSb is formed into about 2.1 nm. This formation of InAs and GaShb is counted as one cycle, and is repeated for example 400 cycles. Next, an n-type superlattice is formed. Specifically, n-type InAs doped with Si and having an electron concentration of about 5×10¹⁷ cm⁻³ is formed into about 4.2 nm, and undoped GaSb is formed into about 2.1 nm. This formation of InAs and GaSb is counted as one cycle, and is repeated for example 50 cycles.

In this way, the light-receiving layer 5 having a superlattice structure in which InAs and GaSb are alternately stacked is formed. Next, as illustrated in FIG. 14, the second electrode layer 6 is formed. Specifically, for example, n-type InAs doped with Si and having an electron concentration of about 1×10¹⁸ cm⁻³ is formed into about 30 nm.

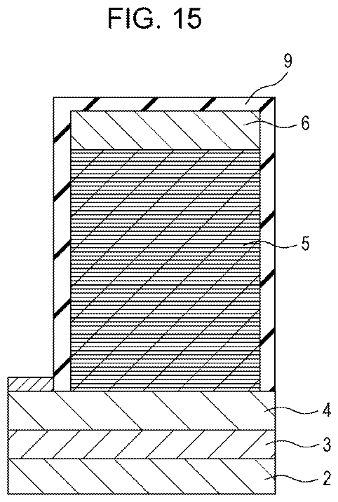

Next, as illustrated in FIG. 15, part of the first electrode layer 4 is exposed by etching using a mask, and an insulating film 9 made of, for example, SiO₂ is formed in such a manner as to cover the exposed front surface of the first electrode layer 4, the side surface of the light-receiving layer 5, and the front surface and the side surface of the second electrode layer 6. Next, the insulating film 9 is selectively etched to expose part of the first electrode layer 4 and the second electrode layer 6 by etching using a mask again, to form an electrode made of, for example, Ti/Pt/Au (see FIG. 10).

In this way, the infrared detector (optical semiconductor device) 1 of the specific configuration example of the embodiment is manufactured (see FIG. 10). According to the infrared detector 1 configured as described above and manufactured in this way, since the light-receiving layer 5 is grown on the substrate 2 having a plane orientation inclined from the (100) plane by 0.3° to the [0-11] direction (α=90°), it is possible to suppress the segregation of In when the GaSb layer is grown on the InAs layer.

For this reason, the film thickness of the InAs layer having the superlattice structure is unlikely to be affected by the film: growth conditions, making it possible to improve the stability of the cutoff wavelength. As a result, the yield is improved. Note that the configuration in this specific configuration example is not limited to this but may be modified as appropriate as long as the modification is within the range that allows the effects to be obtained.

For example, although the inclination angle and the inclination direction of the substrate 2 are 0.3° and the [0-11] direction (α=900), respectively, the configuration is not limited to these. For example, the inclination angle is suffice as long as the inclination angle is greater than 0° and the inclination direction may be the [01-1] direction (α=270°). In particular, the inclination angle of the substrate 2 is preferably within a range of 360°±1°. For example, the substrate 2 may have a plane orientation inclined from the (100) plane by 35.2° to the [0-11] direction (α=90°).

In this case, since the light-receiving layer 5 is grown on the substrate 2 having a plane orientation inclined from the (100) plane by 35.2° to the [0-11] direction (α=90°), the density at the step edge where the growth likely proceeds (the step density) becomes the maximum per unit area. That is, the state where an In atom at the step edge is bound to adjacent As atoms through three bonds is increased, and the replacement with an In atom is most unlikely to occur when a Ga atom supplied is taken in at the step edge.

For this reason, when a GaSb layer is grown on an InAs layer, it is possible to suppress the segregation of In to the maximum extent. Thus, the film thickness of the InAs layer having a superlattice structure is most unlikely to be affected by the film growth conditions, and the stability of the cutoff wavelength is improved to the maximum extent. As a result, the yield is improved to the maximum extent. The substrate 2 suffices as long as the inclination angle to the [0-11] direction or the [01-1] direction is larger than the direction to the [011] direction and the [0-1-1] direction.

For example, the substrate 2 may be such that the plane orientation is inclined from the (100) plane by 1° to the direction of α=80°. In this case, the step is not formed along the direction perpendicular to the inclination direction, but the step along the direction perpendicular to the [0-1-1] direction (α=0°) and the step along the direction perpendicular to the [0-11] direction (α=90°) are formed.

Regarding the density at the step edges where the growth is likely to proceed, the density per unit area at the step edge along the direction perpendicular to the [0-11] direction (α=0°) is larger than the density per unit area at the step edge along the direction perpendicular to the [0-1-1] direction (α=90°). For this reason, it is possible to advantageously obtain the effects in a case of the inclination to the [0-11] direction (α=90°) that suppresses the segregation of In.

As a result, when the GaSb layer is grown on the InAs layer, it is possible to suppress the segregation of In. Accordingly, the film thickness of the InAs layer having the superlattice structure is unlikely to be affected by the film growth conditions, making it possible to improve the stability of the cutoff wavelength and improve the yield. Although the inclination angle of the substrate 2 is set at 1° here, the inclination angle only has to be larger than 0°. Although the inclination direction is set at α=80°, since the same effects are obtained as long as the inclination angle to the [0-11] direction or the [01-1] direction is larger than the inclination angle to the [011] direction and the [0-1-1] direction. For this reason, a only has to be included in the range of 45° to 135° or included in the range of 225° to 315°.

Although the light-receiving layer 5 has the superlattice structure of InAs and GaSb, the configuration is not limited to this. The thickness of each layer may be changed as appropriate depending on the cutoff wavelength. The superlattice structure may be formed any two or more of InAs, InSb, GaSb, and AlSb. A layer formed of a mixed crystal of other materials may be included in the layers of the superlattice in the light-receiving layer 5 as long as these materials respond to the infrared region.

In this case, it is preferable that at least In be contained in the superlattice because this allows the effects to be obtained more favorably. Although the impurities are Si and Be, the impurities are not limited and may be other impurities than Si or Be. For example, Te and Zn may be used as the n-type impurities and the p-type impurities, respectively.

Although the MBE method is used as the staking method for the semiconductor stacked structure 10 included in the infrared detector 1, the staking method is not limited to this. For example, the metal organic chemical vapor deposition (MOCVD) or another method capable of manufacturing a stacked structure may be employed. Although the structure of the infrared detector 1 is the pin type, but is not limited to this. For example, the i layer may be n-type or p-type instead. A barrier layer for suppressing dark current may be inserted as appropriate.

Although in the above-described embodiment and specific configuration example, the plane orientation of the substrate 2 is inclined from the (100) plane, the configuration is not limited to this. The same effects are obtained as long as the plane orientation of the substrate 2 is crystallographically equivalent. Specifically, the same effects are obtained even with the following plane orientation of the substrate 2. For example, the substrate 2 may have a plane orientation inclined from the (010) plane such that the inclination angle to the [10-1] direction or the [−101] direction is larger than the inclination angles to the [101] direction and the [−10-1] direction. In this case as well, the same effects as described above are obtained.

In this case, the substrate 2 only has to be inclined in the range of angle including the [10-1] direction out of the ranges of angle from the [00-1] direction to the [100] direction or be inclined in the range of angle including the [−101] direction out of the ranges of angle from the [001] direction to the [−100]direction. In addition, the substrate 2 only has to be inclined to such a direction that based on the [−10-1] direction, the angle made by the inclination direction and the [−10-1] direction is included in the range of angle of 45° to 135° or 225° to 315°.

In particular, the plane orientation of the substrate 2 is preferably inclined within the range of 36°±1° from the (010) plane to the [10-1] direction or the [−101] direction. In this case, the effects are obtained to the maximum extent. Alternatively, for example, the substrate 2 may have a plane orientation inclined from the (001) plane such that the inclination angle to the [−110] direction or the [1-10] direction is larger than the inclination angles to the [110] direction and the [−1-10] direction. In this case as well, the same effects as described above are obtained.

In this case, the substrate 2 only has to be inclined in the range of angle including the [−110] direction out of the ranges of angle from the [−100] direction to the [010] direction or be inclined in the range of angle including the [1-10] direction out of the ranges of angle from the [100] direction to the [0-10] direction. In addition, the substrate 2 only has to be inclined to such a direction that based on the [−1-10] direction, the angle made by the inclination direction and the [−1-10] direction is included in the range of angle of 45° to 135° or 225° to 315°.

In particular, the plane orientation of the substrate 2 is preferably inclined within the range of 36°±1° from the (001) plane to the [−110] direction or the [1-10] direction. In this case, the effects are obtained to the maximum extent. In other cases as well, the same effects are obtained as long as the configuration is crystallographically equivalent.

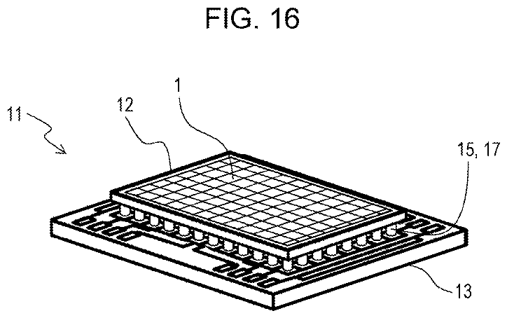

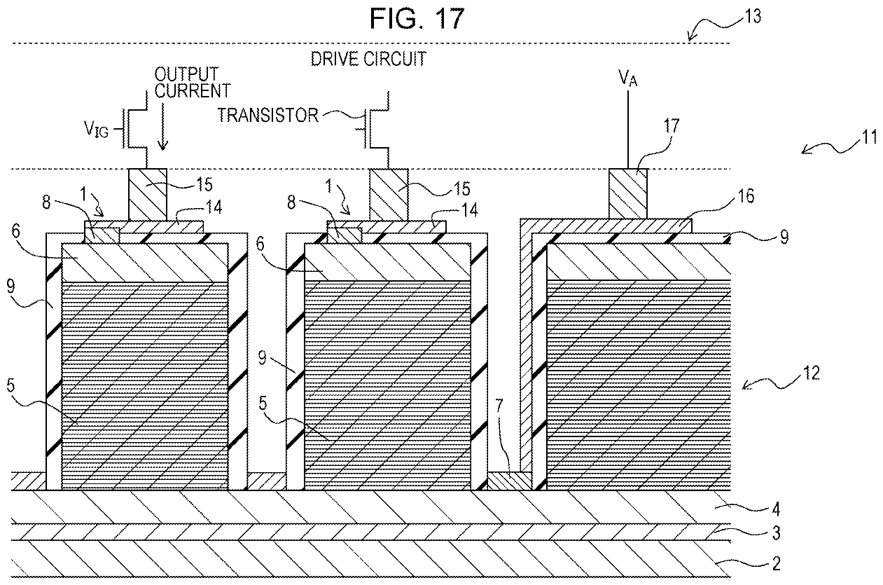

It is also possible, as illustrated in FIGS. 16 and 17 for example, to configure an imaging element (infrared imaging element) 11 by arranging a plurality of pixels on a plane where the infrared detector 1 having the specific configuration example configured as described above (see for example FIG. 10) is used as one pixel. In short, an imaging element (infrared imaging element) 11 including the infrared detector 1 configured as described above may be configured.

As illustrated in FIG. 16 for example, the imaging element 11 includes: an infrared detector array 12 in which a plurality of pixels are arrayed in a plane where the infrared detector 1 having the specific configuration example configured as described above is used one pixel; and a chip 13 connected to the infrared detector array 12 and including a drive circuit and a read-out circuit. As illustrated in FIG. 17 for example, the first electrode layer 4 included in the infrared detector 1 having the specific configuration example configured as described above is used as a common electrode layer commonly used for all the pixels and electrodes (first electrodes) 7 are disposed as common electrodes in peripheral portions of the infrared detector array 12, that is, peripheral portions of regions where the plurality of pixels are arrayed.

The chip 13 including the drive circuit and the read-out circuit is connected via a bump 15 (an output electrode; here an In bump) connected to an electrode (second electrode) 8 included in the infrared detector 1 constituting each pixel by front wiring 14 (metal wiring), and the chip 13 including the drive circuit and the read-out circuit is connected via a bump 17 (a common electrode; here an In bump) connected to the first electrode 7 as the common electrode by front wiring 16 (metal wiring).

The imaging element 11 configured as described above may be manufactured by forming the infrared detector array 12 through film formation, processing, and the like as in the method of manufacturing the above-described specific configuration example, then forming a metal film for the front wirings 14 and 16, forming the In bumps 15 and 17, and then attaching the chips 13 including the drive circuit and the read-out circuit. It is further also possible to configure an imaging system (infrared imaging system) including the imaging element 11 configured as described above.

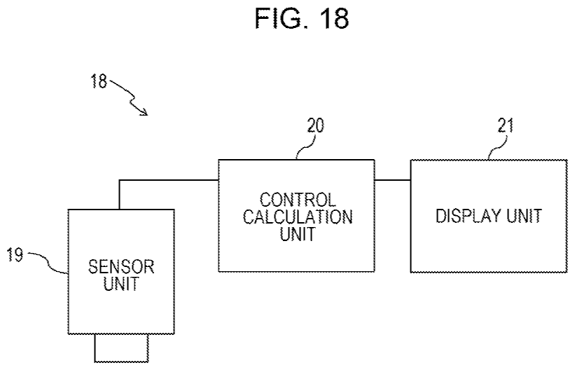

As illustrated in FIG. 18 for example, the imaging system 18 may include: a sensor unit 19 including the imaging element 11 configured as described above; a control calculation unit 20 connected to the sensor unit 19; and a display unit 21, in which an image based on infrared rays incident on the sensor unit 19 is displayed on the display unit 21. In this case, the imaging system 18 is configured as including: the imaging element 11 configured as described above; and the control calculation unit 20 connected to the imaging element 11. The imaging element 11 is sometimes referred to as an image sensor. The control calculation unit 20 may include a central processing unit (CPU), a field-programmable gate array (FPGA), a digital signal processor (DSP), or an application specific integrated circuit (ASIC). The CPU may be a single CPU, a multi CPU, or a multi-core CPU. The display unit 21 includes a display.

Hence, the infrared detector (optical semiconductor device) 1 and the imaging element 11 according to the embodiment exhibits the effects that reduce the instability of the cutoff wavelength caused by the segregation and improves the yield. Note that although in the above-described embodiment and specific configuration example, the case in which the disclosure is applied to the optical semiconductor device including the light-receiving layer that absorbs light (specifically, the infrared detector 1 including the light-receiving layer 5 that absorbs infrared rays) is described as an example, the configuration is not limited to this.

For example, the disclosure may be applied to an optical semiconductor device (a light-emitting device) including a light-emitting layer that emits light. The light-emitting device may include at least one of a laser diode, a light emitting diode (LED), and the like. In this case, when the light-emitting layer included in the optical semiconductor device (light-emitting device) is configured in the same manner as the light-receiving layer 5 of the above-described embodiment or the specific configuration example (for example configured to have a superlattice structure), using the inclined substrate 2 of the above-described embodiment or the specific configuration example makes it possible to reduce the instability of the light emission wavelength caused the segregation and to improve the yield.

Specifically, the same problem as in the above-described embodiment occurs also in a light-emitting device (optical semiconductor device) including a light-emitting layer having a structure in which a plurality of semiconductor layers are stacked above a substrate. In this case, it is difficult to stably obtain a desired light emission wavelength, which leads to a low yield. In view of this, applying the disclosure and using the inclined substrate 2 of the above-described embodiment or the specific configuration example makes it possible to reduce the instability of the light emission wavelength caused by segregation and to improve the yield.

As described above, in an optical semiconductor device including a light-receiving layer or a light-emitting layer having a structure in which a plurality of semiconductor layers are stacked above a substrate, the same problem as in the above-described embodiment occurs. In this case, it is difficult to stably obtain a desired cutoff wavelength or a desired light emission wavelength, which leads to a low yield. In view of this, applying the disclosure and using the inclined substrate 2 of the above-described embodiment or specific configuration example makes it possible to reduce the instability of the cutoff wavelength or the light emission wavelength caused by the segregation and to improve the yield.

Note that the disclosure is not limited to the configurations described in the above-described embodiment and modifications, but various modifications may be made without departing from the scope of the disclosure.

All examples and conditional language provided herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that the various changes, substitutions, and alterations could be made hereto without departing from the spirit and scope of the invention.

What is claimed is:

1. An apparatus comprising:
a substrate that has a plane orientation inclined from a (100) plane such that an inclination angle to a [0-11] direction or a [01-1] direction is larger than an inclination angle to a [011] direction and a [0-1-1] direction, or inclined from a (010) plane such that an inclination angle to a [10-1] direction or a [−101] direction is larger than an inclination angle to a [101] direction and a [−10-1] direction, or inclined from a (001) plane such that an inclination angle to a [−110] direction or a [1-10] direction is larger than an inclination angle to a [110] direction and the [−1-10] direction; and
a light-receiving layer disposed above the substrate and having a structure in which a plurality of semiconductor layers are stacked.

2. The apparatus according to claim 1, wherein
the substrate is a compound semiconductor substrate, and
the plurality of semiconductor layers are each a compound semiconductor layer.

3. The apparatus according to claim 1 wherein
the light-receiving layer has a superlattice structure in which a plurality of III-V-group compound semiconductor layers are stacked as the structure in which the plurality of semiconductor layers are stacked.

4. The apparatus according to claim 3, wherein
the plurality of II-V-group compound semiconductor layers include any two or more selected from a layer containing InAs, a layer containing GaSb, a layer containing AlSb, and a layer containing InSb.

5. The apparatus according to claim 3, wherein
the plurality of III-V-group compound semiconductor layers include at least a III-V-group compound semiconductor layer containing In.

6. The apparatus according to claim 4, wherein
the substrate is a GaSb substrate or an InAs substrate.

7. The apparatus according to claim 1, wherein
the substrate is such that
where the plane orientation is inclined from the (100) plane, the plane orientation is inclined in a range of angle including the [0-11] direction out of ranges of angle from the [0-10] direction to the [001] direction or inclined in a range of angle including the [01-1] direction out of ranges of angle from the [010] direction to the [00-1] direction,
where the plane orientation is inclined from the (010) plane, the plane orientation is inclined in a range of angle including the [10-1] direction out of ranges of angle from the [00-1] direction to the [100] direction or inclined in a range of angle including the [−101] direction out of ranges of angle from the [001] direction to the [−100] direction, and
where the plane orientation is inclined from the (001) plane, the plane orientation is inclined in a range of angle including the [−110] direction out of ranges of angle from [−100] direction to the [010] direction or inclined in a range of angle including the [1-10] direction out of ranges of angle from the [100] direction to the [0-10] direction.

8. The apparatus according to claim 1, wherein
the substrate is such that
where the plane orientation is inclined from the (100) plane, the plane orientation is inclined to such a direction that based on the [0-1-1] direction, an angle made by an inclination direction and the [0-1-1] direction is included in a range of angle of 45° to 135° or 225° to 315°,
where the plane orientation is inclined from the (010) plane, the plane orientation is inclined to such a direction that based on the [−10-1] direction, an angle made by the inclination direction and the [−10-1] direction is included in the range of angle of 45° to 135° or 225° to 315°, and
where the plane orientation is inclined from the (001) plane, the plane orientation is inclined to such a direction that based on the [−1-10] direction, an angle made by the inclination direction and the [−1-10] direction is included in the range of angle of 45° to 135° or 225° to 315°.

9. The apparatus according to claim 1, wherein
the substrate is such that
where the plane orientation is inclined from the (100) plane, the plane orientation is inclined from the (100) plane within a range of 36°±1° to the [0-11] direction or the [01-1] direction,
where the plane orientation is inclined from the (010) plane, the plane orientation is inclined within the range of 36°±1° from the (010) plane to the [10-1] direction or the [−101] direction, and
where the plane orientation is inclined from the (001) plane, the plane orientation is inclined within the range of 36°±1° from the (001) plane to the [−110] direction or the [1-10] direction.

10. The apparatus according to claim 1, wherein
the substrate is such that
where the plane orientation is inclined from the (100) plane, the plane orientation is inclined within a range of ±1° about a (2-11) plane or a (21-1) plane,
where the plane orientation is inclined from the (010) plane, the plane orientation is inclined within the range of ±1° about a (12-1) plane or a (−121) plane, and
where the plane orientation is inclined from the (001) plane, the plane orientation is inclined within the range of ±1° about a (−112) plane or a (1-12) plane.
